(19) United States
(12) Patent Application Publication
(10) Pub. No.: US 2010/0027704 A1
(43) Pub. Date: Feb. 4, 2010

(54) Method and Apparatus for Data Transmission Based on Signal Priority and Channel Reliability

(75) Inventors: Chung-Lien HO, Taoyuan County (TW); Chien-Min LEE, Xinzhuang City (TW)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: Industrial Technology Research Institute

(21) Appl. No.: 12/536,032

(22) Filed: Aug. 5, 2009

Related U.S. Application Data
(63) Continuation-in-part of application No. 12/177,070, filed on Jul. 21, 2008.
(60) Provisional application No. 61/143,943, filed on Jan. 12, 2009.
(60) Provisional application No. 60/971,236, filed on Sep. 10, 2007.
(60) Provisional application No. 60/986,228, filed on Nov. 7, 2007.
(60) Provisional application No. 60/988,051, filed on Nov. 14, 2007.

(51) Int. Cl. H04L 1/02; H03M 13/00

(52) U.S. Cl. 375/267; 714/755; 714/E11.001

(57) ABSTRACT

Various methods for data transmission based on signal priority and channel reliability are provided. One example method includes encoding a number of bits into coded bits including systematic bits and respective associated parity bits, the bits being encoded for transmission via channels of a multi-channel communications system including a more reliable channel and a less reliable channel. The example method also includes allocating the systematic bits to bit locations within a first stream corresponding to the more reliable channel, allocating the systematic bits to bit locations having a higher signal priority within a second stream corresponding to the less reliable channel, and allocating the parity bits to bit locations within the second stream. Similar and related example methods and apparatuses for allocating the systematic and parity bits to the respective bit locations in both the more and less reliable channels are also provided.

### CROSS-REFERENCE TO RELATED APPLICATIONS

This application claims the benefit of U.S. Provisional Application No. 61/143,943 filed Jan. 12, 2009, and is a continuation-in-part of U.S. application Ser. No. 12/177,070 filed Jul. 21, 2008, now published as U.S. Patent Publication No. 2009/0067543, which in turn claims the benefit of U.S. Provisional Application Nos. 60/971,236, filed Sep. 10, 2007; 60/986,228, filed Nov. 7, 2007; and 60/988,051, filed Nov. 14, 2007. The contents of U.S. Provisional Application Nos. 61/143,943, 60/986,228, 60/988,051; and U.S. application Ser. No. 12/177,070 are hereby incorporated by reference in their respective entireties.

### TECHNICAL FIELD

Example embodiments of the present disclosure generally relate to data communications and, more particularly, to data processing for transmission in a multi-channel communication system.

### BACKGROUND

A multi-channel communication system refers to a wireless communication system capable of transmitting information such as voice and data between a transmitter and a receiver, which may have more than one transmitter antenna and receiver antenna, respectively. Such a multi-channel system may include, for example, a multiple-input multiple-output (MIMO) communication system, an orthogonal frequency division modulation (OFDM) system and/or a MIMO system based on OFDM. A MIMO system may employ multiple transmitter antennas and multiple receiver antennas to exploit spatial diversity to support a number of spatial subchannels, each of which may be used to transmit data. An OFDM system may partition an operating frequency band into a number of frequency subchannels, each of which is associated with a respective subcarrier on which data may be modulated. A multi-channel communication system may therefore support a number of “transmission channels,” each of which may correspond to a spatial subchannel in a MIMO system, a frequency subchannel in an OFDM system, or a spatial subchannel of a frequency subchannel in a MIMO system that utilizes OFDM.

In a multi-channel communication system, transmission channels may experience different channel conditions due to, for example, different fading and multipath effects, and may therefore experience different signal-to-interference-plus-noise ratios (SNRs). Consequently, the supported transmission capacities (e.g., the information bit rates) supported by the transmission channels may be different from channel to channel. Moreover, the channel conditions may often vary over time and/or frequency. As a result, the bit rates supported by the transmission channels may also vary due varying channel conditions and reliability. In this regard, a single channel experiencing poor conditions can often limit the aggregate transmission rate of the collection of channels. As such, applications operating with respect to communicated data may be slow and user experience may suffer.

### BRIEF SUMMARY

Example methods and example apparatuses are described herein that provide for data transmission based on signal priority and signal/channel reliability. Example embodiments leverage feedback indicating which of a plurality of channels has a higher reliability, and allocate higher importance data bits to bit locations within data streams for transmission based on channel reliability. Additionally, example embodiments selectively allocate higher importance data bits to higher signal priority locations within modulated data symbols to increase the likelihood of successful transmission of the associated information.

According to some example embodiments, information bits to be transmitted may be first encoded to generate systematic bits and parity bits. As used herein, systematic bits may be encoded bits that describe the data of the information bits that were inputs to the encoder, and may be of higher importance to successful communications. Parity bits may be encoded error correction and error verification bits, and may therefore be of lesser importance to successful communications. Example embodiments allocate systematic bits and parity bits within data streams corresponding to channels of a multi-channel system to increase communications throughput and overall reliability.

Various example embodiments are described herein. One example embodiment is a method for data transmission based on signal priority and channel reliability. The example method includes encoding a number of bits into coded bits including systematic bits and respective associated parity bits, the bits being encoded for transmission via channels of a multi-channel communications system including a more reliable channel and a less reliable channel. The example method also includes allocating the systematic bits and the parity bits to respective bit locations within a first stream corresponding to the more reliable channel, or respective bit locations within a second stream corresponding to the less-reliable channel. Allocating the systematic bits and the parity bits may include allocating at least some systematic bits to bit locations within the first stream including allocating at least some systematic bits to bit locations having a higher signal priority within the first stream, and allocating at least some parity bits having associated systematic bits allocated to the first stream to bit locations within the second stream.

Another example embodiment is an apparatus for data transmission based on signal priority and channel reliability. According to some example embodiments, the apparatus comprises an encoder and a bit mapper. The encoder may be configured to encode a number of bits into coded bits including systematic bits and respective associated parity bits, the bits being encoded for transmission via channels of a multi-channel communications system including a more reliable channel and a less reliable channel. The bit mapper may be configured to allocate the systematic bits and the parity bits to respective bit locations within a first stream corresponding to the more reliable channel, or respective bit locations within a second stream corresponding to the less-reliable channel. Being configured to allocate the systematic bits and the parity bits may include being configured to allocate at least some systematic bits to bit locations within the first stream including being configured to allocate at least some systematic bits to bit locations having a higher signal priority within the first stream. The bit mapper may also be configured to allocate at least some parity bits having associated systematic bits allocated to the first stream to bit locations within the second stream.

Another example embodiment is an example computer program product for data transmission based on signal priority and channel reliability. The example computer program product comprises at least one computer-readable storage medium having executable computer-readable program code instructions stored therein. The computer-readable program code instructions of the example computer program product are for causing an apparatus to perform encoding a number of bits into coded bits including systematic bits and respective associated parity bits, the bits being encoded for transmission via channels of a multi-channel communications system including a more reliable channel and a less reliable channel. The computer-readable program code instructions may also cause the apparatus to perform allocating the systematic bits and the parity bits to respective bit locations within a first stream corresponding to the more reliable channel, or respective bit locations within a second stream corresponding to the less-reliable channel. Allocating the systematic bits and the parity bits may include allocating at least some systematic bits to bit locations within the first stream including allocating at least some systematic bits to bit locations having a higher signal priority within the first stream. The computer-readable program code instructions may also cause the apparatus to perform allocating at least some parity bits having associated systematic bits allocated to the first stream to bit locations within the second stream.

### BRIEF DESCRIPTION OF THE DRAWING(S)

Having thus described example embodiments in general terms, reference will now be made to the accompanying drawings, which are not necessarily drawn to scale, and wherein:

FIG. 1 illustrates a schematic block diagram of a transmitter based on a single codeword (SCW) in a multiple-input multiple-output system;

FIG. 2 illustrates a schematic block diagram of a channel encoder;

FIG. 3 illustrates a block diagram of channel interleaving and puncturing;

FIGS. 4a-4c illustrate schematic block diagrams of codeword-to-stream mapping for SCW-based transmission with different numbers of streams;

FIG. 5a illustrates data processing a bit allocation for a SCW-based scenario;

FIGS. 5b and 5c illustrate 16QAM constellations indicating bit reliabilities;

FIG. 6 illustrates a schematic block diagram of a transmitter based on a multiple codeword (MCW) in a multiple-input multiple-output system;

FIGS. 7a-7b illustrate schematic block diagrams of codeword-to-stream mapping for MCW-based transmission with different numbers of streams;

FIG. 8 illustrates a schematic block diagram of a transmitter based on a single codeword (SCW) in a multiple-input multiple-output system according to an example embodiment;

FIGS. 9, 11, 13, and 15 illustrate bit allocation techniques based on signal priority and channel reliability according to example embodiments;

FIGS. 10, 12, 14, and 16 illustrate flow charts of methods for implementing bit allocation techniques based on signal priority and channel reliability according to example embodiments; and

FIG. 17 illustrates an apparatus for implementing bit allocation techniques based on signal priority and channel reliability according to various example embodiments.

### DETAILED DESCRIPTION

Example embodiments will now be described more fully hereinafter with reference to the accompanying drawings, in which some, but not all embodiments are shown. Indeed, the embodiments may take many different forms and should not be construed as limited to the embodiments set forth herein; rather, these embodiments are provided so that this disclosure will satisfy applicable legal requirements. Like reference numerals refer to like elements throughout. The terms “data,” “content,” “information,” and similar terms may be used interchangeably, according to some example embodiments, to refer to data capable of being transmitted, received, operated on, and/or stored.

As mentioned above, multi-input multi-output (MIMO) technologies may employ multiple antennas at a transmitter and receiver to simultaneously transmit multiple independent data streams for increasing the transmission rate. Techniques employing this principle are being adopted in 4^{th} Generation wireless communication standards in combination with some MIMO modes specified in the IEEE 802.16e standards. Regardless of the specific techniques, frameworks for MIMO transmissions may be based on a single codeword (SCW) structure or a multiple codeword (MCW) structure.

For an SCW structure, one modulation and coding scheme (MCS), which includes a modulation order and a coding rate, may be used in the transmitter. On the other hand, an MCW structure may use multiple sets of MCS (e.g., two sets). Based on either of these techniques, some parameters at the transmitter, such as the modulation order and coding rate, may be adapted to improve the transmission performance. MCW may provide some performance gain over SCW due to more parameters being available for modification. However, additional feedback overhead may be required, which may lead to reduced overall spectral efficiency.

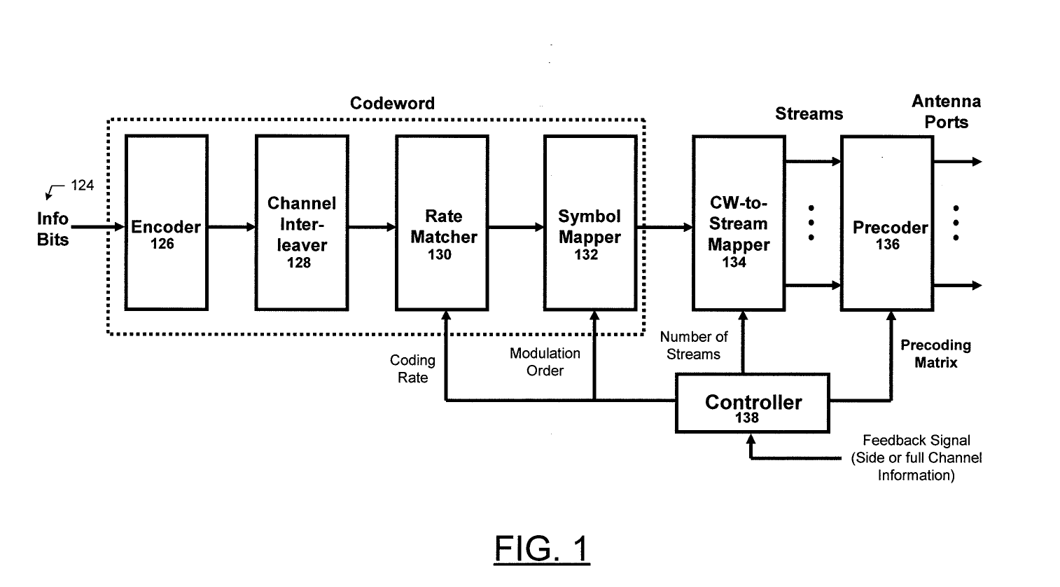

FIG. 1 is a schematic block diagram of a transmitter for SCW-based spatial multiplexing MIMO with precoding. The transmitter may include an encoder 126, a channel interleaver 128, a rate matcher 130, a symbol mapper 132, a codeword (CW)-to-stream mapper 134, a precoder 136 in connection with a number of antenna ports, and a controller 138. The encoder 126 may receive a code block containing information bits 124 in a bit stream. The encoder 126 may then encode the received information bits 124 in accordance with a code scheme, for example, a ⅓-rate turbo code (TC) with tail bit addition.

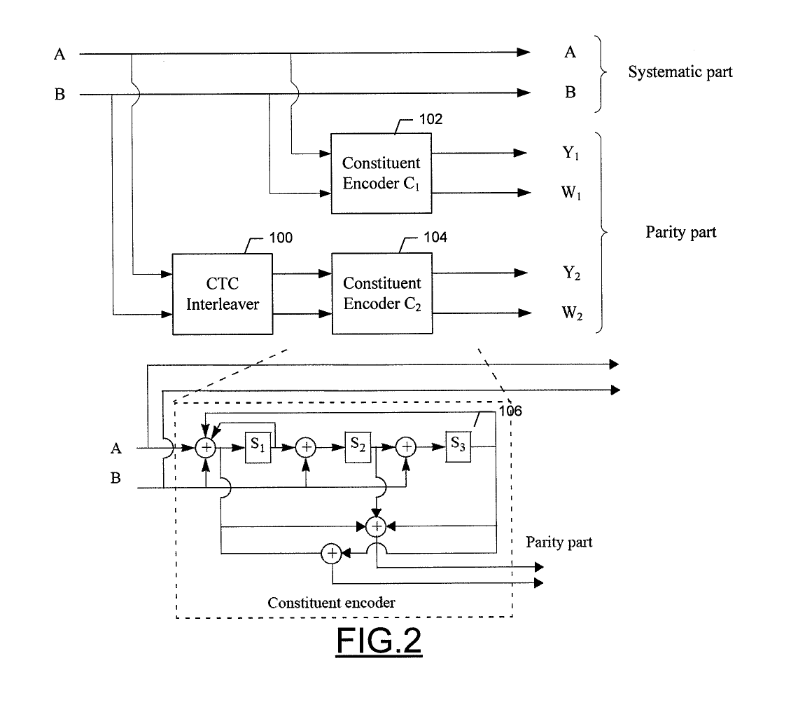

The TC or convolutional turbo code (CTC) may use a double binary circular recursive systematic convolutional code, as is shown in FIG. 2, which depicts a more specific illustration of the encoder 126. The input information bits (A, B) may be first encoded via CTC as the systematic bits (A, B) and parity bits (Y1, Y2, W1, W2). Each systematic bit may be associated with one or more parity bits, the parity bits being configured for error detection and/or correction of an associated systematic bit. Parity bits Y1 and W1 may be generated via constituent encoder 102, and parity bits Y2 and W2 may be generated via CTC interleaver 100 and constituent encoder 104.

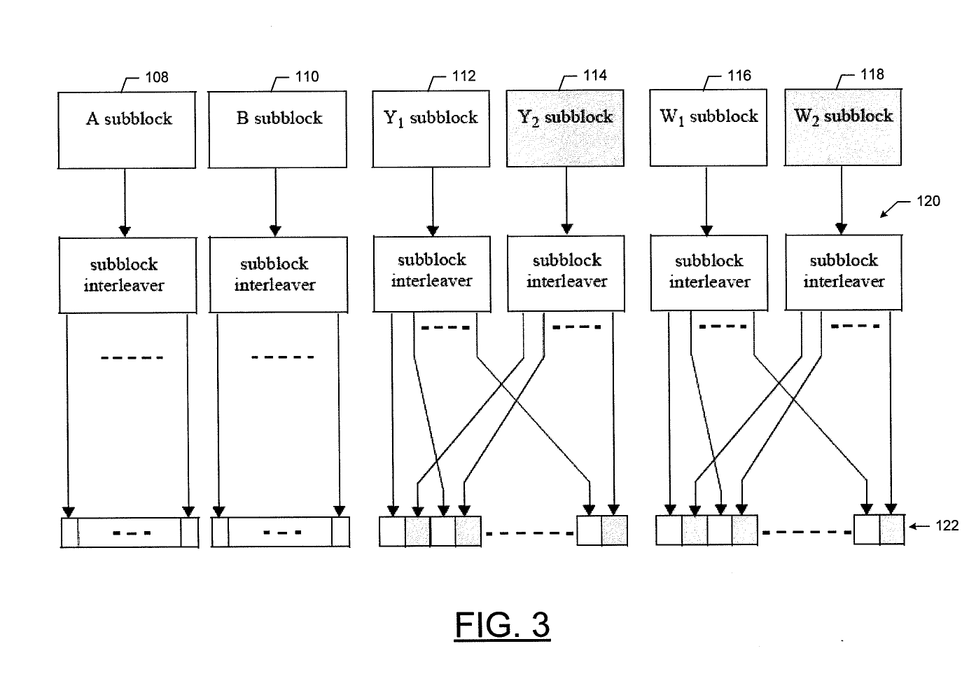

After encoding, the subblocks of encoded bits may be interleaved via channel interleaver 128 to protect against burst-type communications errors on a particular channel. Referring to FIG. 3, each subblock of bits (e.g., A subblock 108, B subblock 110, Y1 subblock 112, Y2 subblock 114, W1 subblock 116, W2 subblock 118) may be routed through the subblock interleavers 120 to generate an interleaved code sequence 122.

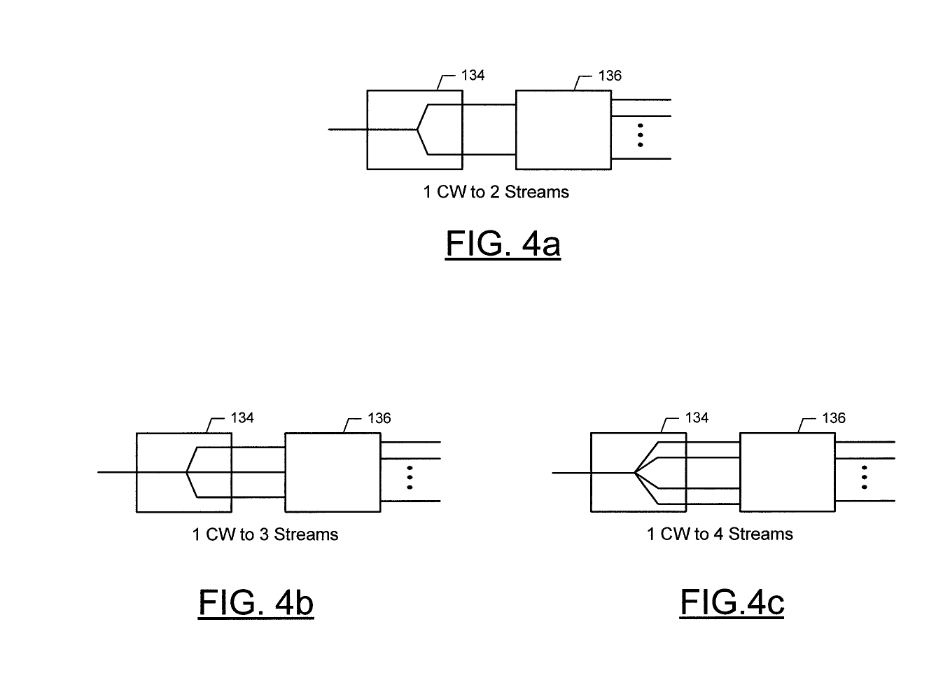

Subsequent to interleaving, the interleaved code sequence 122, which includes the systematic part and parity part, may be punctured to match the desired coding rate by the rate matcher 130. After puncturing, the coded bits may be modulated by the symbol mapper 132 as complex-valued symbols. The modulated symbols may then be converted from a single sequence to multiple transmission streams via a CW-to-stream mapper 134, where, for example, a circulation-based CW-to-stream mapping may be used. The streams may then be precoded in the precoder 136 by a pre-designed precoding matrix and transmitted from the multiple antennas. FIGS. 4a through 4c depict the CW-to-stream mapper 134 and the precoder 136 according to various configurations for generating a plurality of streams. FIGS. 4a, 4b, and 4c depict a scenario where the CW-to-stream mapper 134 converts a single coded, modulated symbol sequence to 2, 3, and 4 streams, respectively. Based on the forgoing, the coding rate, modulation order, number of transmission data streams and precoding matrix may be adapted by the controller 138 to modify the resultant transmission.

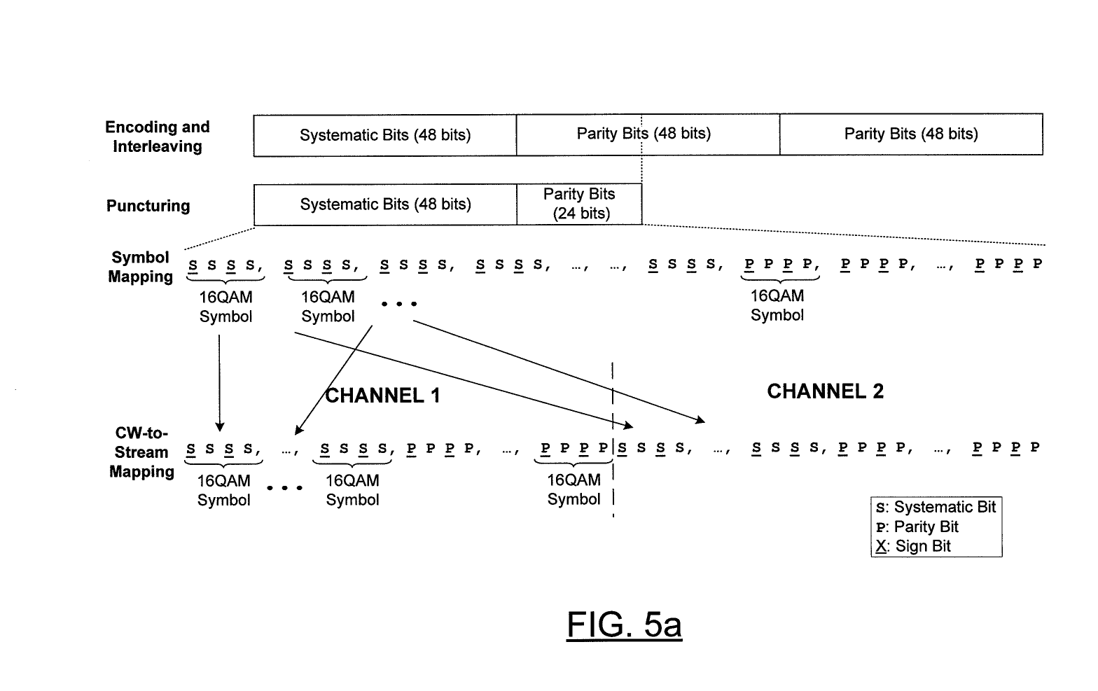

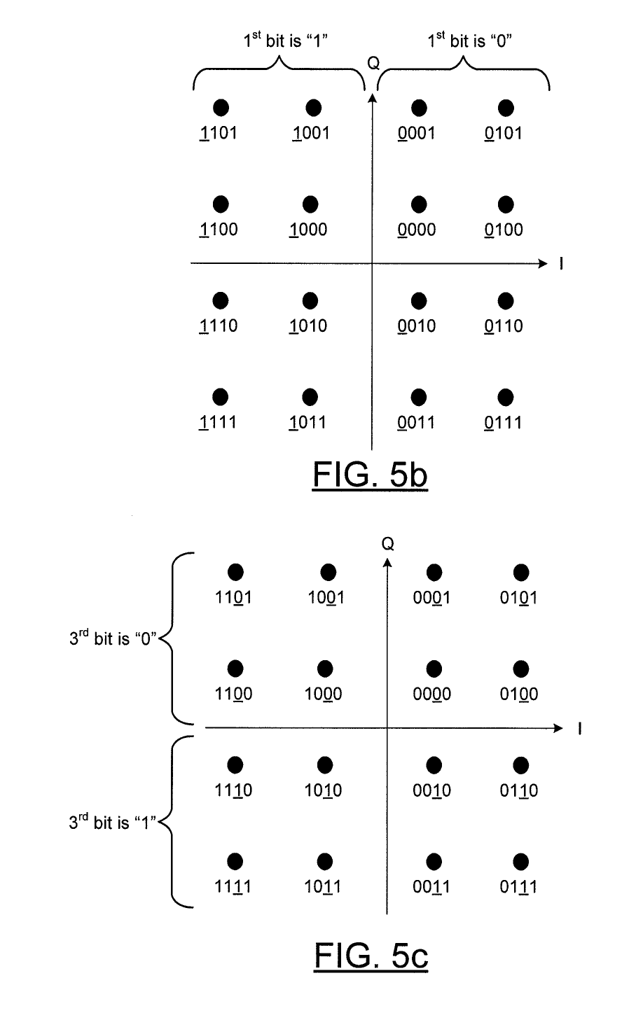

FIG. 5a depicts an example of data processing for a SCW-based spatial multiplexing MIMO transmission where the number of information bits Nₑₚ is 48, 16QAM modulation is used, the code rate R is ⅔, and number of streams L is 2. In this example, 48-information bits are first encoded by a ⅓-rate mother CTC, and then passed through interleaving and puncturing to match to ⅔ coding rate. Accordingly, 48 systematic bits are included in the coded bit sequence with the remaining 24 coded bits being parity bits after puncturing. The parity bits may follow the systematic bits in a coded bit sequence. After puncturing, the coded bits may then be mapped into symbols via the symbol mapper 132, where four coded bits are grouped and mapped into one complex-valued modulation symbol due to 16QAM modulation.

Each symbol may have associated bit locations having a higher signal priority (e.g., sign bits) and bit locations having a lower signal priority (e.g., non-sign bits). The underlined bits in FIG. 5a, represent the sign bits of a complex-valued modulation symbol, which may be used to stand for the real value and image value of a complex-valued modulation symbol. Due to the construction of the symbol, the sign bits have a higher signal priority than the non-sign bits. In general, a complex-valued modulation symbol may consist of multiple (coded) bits. For example two bits comprise a Quadrature Phase-shift keying (QPSK) symbol, four bits comprise a sixteen Quadrature Amplitude Modulated (16QAM) symbol, and six bits comprise a sixty-four Quadrature Amplitude Modulated (64QAM) symbol. Two bits may represent the real (i.e., in-phase) part and image (i.e., quadrature) part of a QAM symbol, which may be referred to as sign bits. FIGS. 5b and 5c illustrate constellations for the encoding for 16QAM modulation, in which the first bit and third bit, respectively, characterize the sign of the real part and image part. As indicated in FIGS. 5b and 5c, changes to the first and third bits define respective halves of the constellations (i.e., the first bit is a 1 in the left half and a 0 in the right half, and the third bit is a 0 in the top half and a 1 in the bottom half). During symbol transmission, errors often occur in demodulation regions in the same half or quadrant. As such, the error probability of half or quadrant determining bits have a relatively high probability, in comparison to bits that do not define a half or a quadrant. These bits may therefore have a higher signal priority and may be more important in transmission. Based on this property, more significant coded bits (i.e., systematic bits) may be allocated to the sign bits of a complex-valued modulation symbol for reliability considerations.

Referring again to the example scenario of FIG. 5a, a total 72 coded bits are mapped into 18 16QAM modulation symbols. In accordance with this example scenario, it can be seen that some of the systematic bits are allocated to the non-sign bits of the complex-valued modulation symbols. Finally, the 18 modulated symbols are evenly allocated to two transmission streams via a circulation-based CW-to-stream mapper 134, and then transmitted via two effective channels. As indicated by the arrows in FIG. 5a, systematic bits and associated parity bits are allocated to the same channels. Based on the discussion above, it may be assumed that one of the channels may have better, more reliable transmission quality than the other. However, in accordance with this example scenario, the channels experience uniform treatment with respect to allocation of the bits. In this case, some of the systematic bits will be allocated into the less reliable channel due to an R=⅔ coding rate.

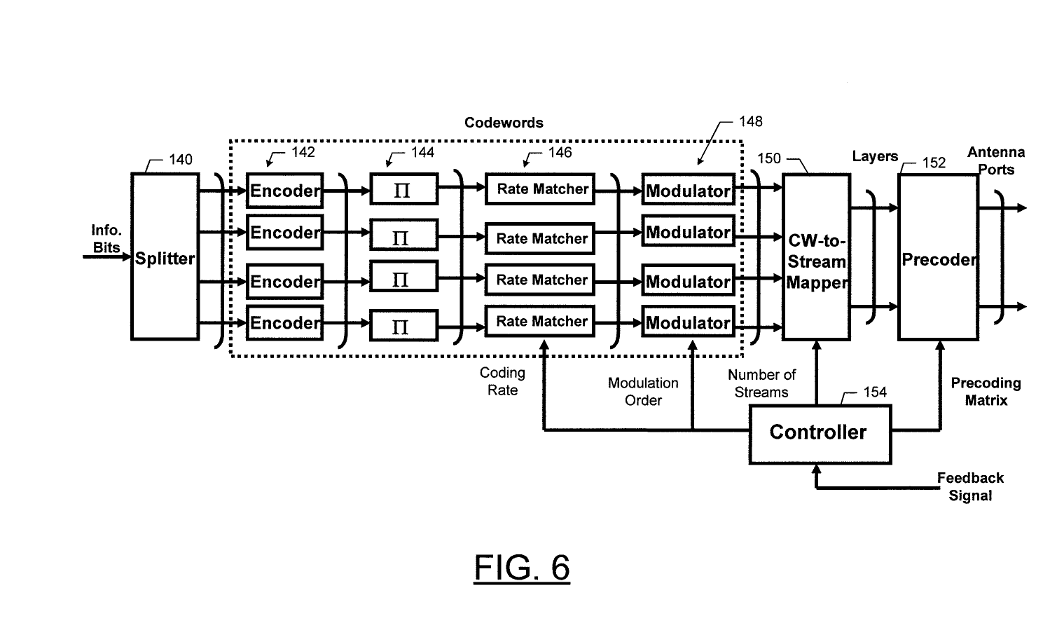

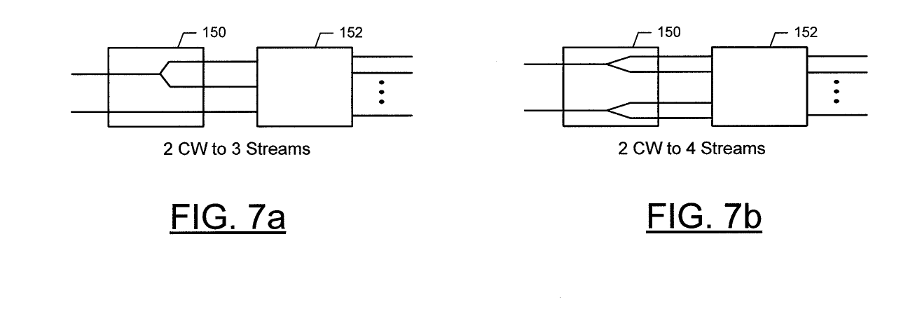

FIG. 6 is a schematic block diagram of a transmitter for MCW-based spatial multiplexing MIMO with precoding. The transmitter may include a splitter 140, encoders 142, channel interleavers 144, rate matchers 146, modulators 148, a codeword (CW)-to-stream mapper 150, a precoder 152 in connection with a number of antenna ports, and a controller 154. For the MCW-based structure, a number of MSCs may be adapted by the controller 154 according to the channel conditions. Compared to the SCW structure described above, more parameters may be adjusted for channel variations to provide improved link performance. However, the increased number of modifiable parameters may result in the need for increased feedback overhead. Thus, the MCW structure operates similar to the SCW structure, but with respect to multiple codewords. FIGS. 7a and 7b depict how the CW-to-stream mapper 150 and precoder 152 may operate. In this regard, FIGS. 7a and 7b depict scenarios where the CW-to-stream mapper 150 converts two coded, modulated symbol sequences to 3 and 4 streams, respectively.

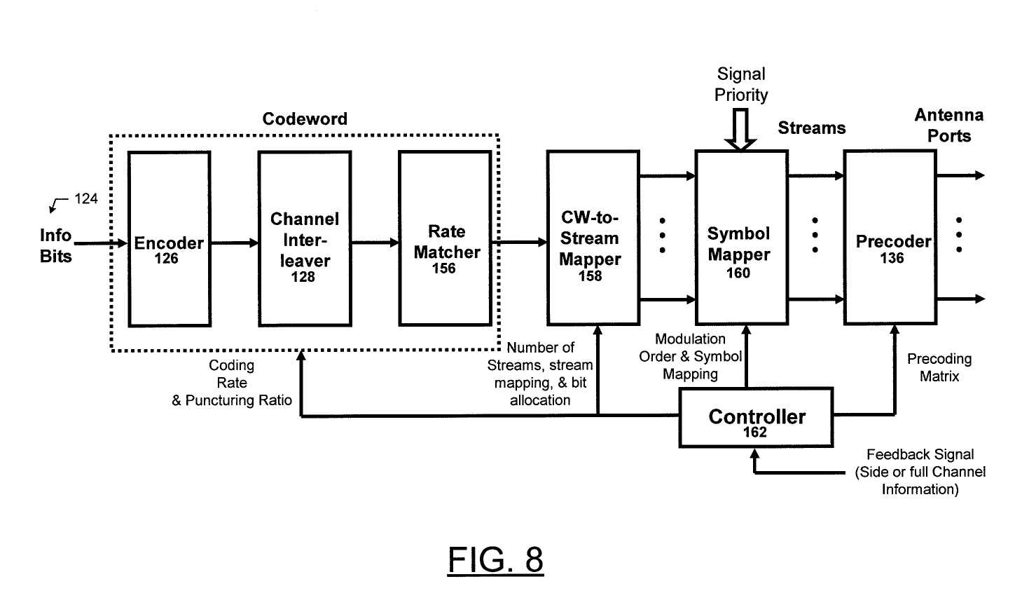

FIG. 8 depicts an example SCW structure in accordance with various example embodiments. The structure of FIG. 8 illustrates a schematic block diagram supporting an example method and/or example apparatus for data allocation based on the signal priority and reliability to improve the transmission quality. While the structure of FIG. 8 is depicted with respect to an SCW solution, one of skill in the art would appreciate that embodiments are equally applicable to MCW structure. The encoder 126, the channel interleaver 128, the rate matcher 156, the CW-to-stream mapper 158, the symbol mapper 160, the precoder 136, and the controller 162 may be embodied as one or more hardware devices (e.g., integrated circuits) that are either hardware or software configured.

Referring to FIG. 8, the encoder 126, the channel interleaver 128 and the precoder 136 may operate as described above. However, according to some example embodiments, after interleaving, the coded bits may be rate matched based on a coding rate and signal reliability by the rate matcher 156. In this regard, according to various example embodiments, the rate matcher 156 may puncture parity bits from the coded sequence based on a puncturing ratio or puncturing rule determined by the controller 162 based on channel reliability and/or bit allocations. The puncturing ratio may indicate the ratio of parity bits associated with systematic bits allocated to a stream corresponding to a more reliable channel, to parity bits associated with systematic bits allocated to a stream corresponding to a less reliable channel. According to various example embodiments, the puncturing ratio may be determined such that parity bits associated with systematic bits allocated to a stream corresponding to a less reliable channel are larger in number than the parity bits associated with systematic bits allocated to a stream corresponding to a more reliable channel. For example a 1:2 ratio may indicate that the systematic bits in the less reliable channel have double the number of parity bits, as compared to the systematic bits in the more reliable channel.

The CW-to-stream mapper 158 and the symbol mapper 160, which may be collectively referred to as a bit mapper, may be configured to allocate systematic and parity bits to various streams based on the reliability of the channels. In this regard, the coded bits after interleaving are first punctured and mapped to streams based on the signal reliability, and the bits in each of streams are then mapped into modulation symbols by the symbol mapper 160 based on both the signal priority and reliability. As such, in contrast to the CW-to-stream mapper 134, the CW-to-stream mapper 158 is configured to perform stream mapping at the bit level, rather than at the symbol level.

According to various example embodiments, symbol mapping may be performed based on the priority of the modulation symbol (i.e., modulation) to further improve the transmission link quality. According to various example embodiments, Symbol Mapping based on Priority (SMP) may be utilized. Based on SMP, systematic bits (i.e., the significant part of the code sequence) may be allocated to the high signal priority bit locations within a complex-value modulation symbol (e.g., sign bits). Further, according to various example embodiments, the systematic bits may also be allocated to a stream corresponding to a more reliable channel based on feedback information from, for example, a receiver or other network entity.

Compared to parity bits, the systematic bits may have increased importance within the coded bit sequence because the systematic bits may be the information bits. Allocating the systematic bits into more reliable channel may provide for an improved transmission link quality when the signal reliability on each of channels is available at the transmitter. As such, according to various example embodiments, as many systematic bits as possible may be allocated to the more reliable channel. However, based on the coding rate, situations may arise where at least some systematic bits are allocated to a less reliable channel.

The information used to indicate which channel is more reliable may result in an increase of feedback overhead via the feedback signal to the controller 162. However, according to various example embodiments, the feedback overhead is limited to the number of bits needed to describe, for example, which channel has the best reliability. According to various example embodiments, 1 to 3 bits may be sufficient for the feedback overhead. In some example embodiments, such as a MIMO system operating with two data streams corresponding to respective channels, a one-bit overhead may be fed back to the transmitter in an open-loop MIMO system to indicate the channel quality. For situations where N_{S} transmission streams are utilized, log₂N_{S} bits may be used for channel reliability reporting. In some closed loop systems, channel reliability information may be already available at the transmitter side and no additional overhead is therefore required. As a result, bit allocation based on signal priority combined with allocation based on channel reliability may therefore be used to develop a joint allocation for improving link reliability and increasing overall spectral efficiency.

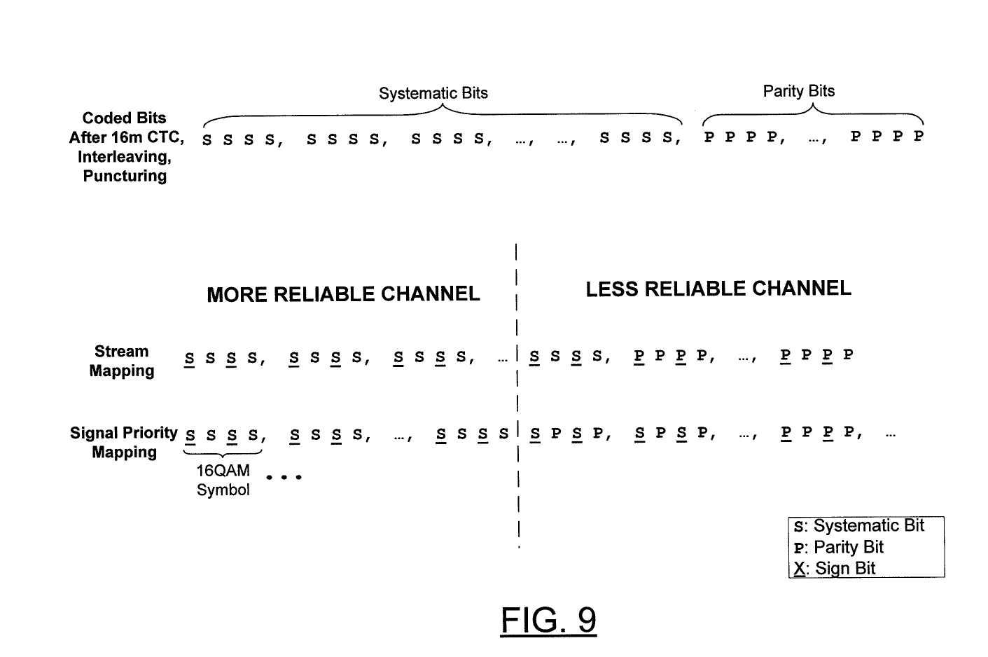

Based on the forgoing, FIGS. 9, 11, 13, and 15 depict bit allocation results of various example embodiments. It should be noted that while the content of FIGS. 9, 11, 13, and 15 describe situations involving a two effective channel system, it is contemplated that the techniques and embodiments described may be applied to system employing any number of channels. FIG. 9 depicts a bit allocation determined using CW-to-stream mapping based on signal/channel reliability combined with symbol mapping based on signal priority. In the example scenario depicted in FIG. 9, the number of information bits is 48, 16QAM modulation is used with a code rate ⅔, and two data streams are generated for transmission on respective channels. One channel has been determined to be more reliable than the other channel via, for example, feedback received by the controller 162.

As depicted in FIG. 9, a sequence of coded systematic and parity bits may be generated after encoding, interleaving, and puncturing. The resultant coded bits may then be mapped through a CW-to-stream mapper based on signal reliability. In this regard, the systematic bits may be mapped to a stream corresponding to the more reliable channel. Any remaining systematic bits may be allocated to less reliable channel, and all of the parity bits may be allocated to the stream corresponding to the less reliable channel. Symbol mapping in accordance with SMP may then be performed whereby, systematic bits allocated to the stream corresponding to the less reliable channel may be allocated to high signal priority bit locations (e.g., sign bit locations) of the complex-valued symbols within the stream corresponding to the less reliable channel. The parity bits may be allocated to the lower signal priority locations (e.g., non-sign bit locations) within the stream corresponding to the less reliable channel. Accordingly, the operations result in a first stream of all systematic bits for the more reliable channel, and a second stream having systematic bits in high signal priority bit locations, parity bits in any remaining high signal priority bit locations, and parity bits in the lower signal priority bit locations for the less reliable channel.

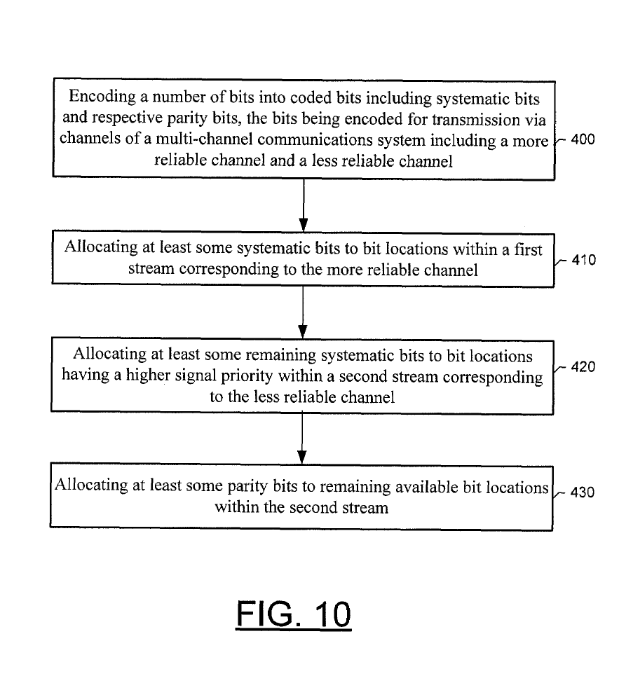

FIG. 10 depicts a flow chart of an example method for achieving the bit allocation of FIG. 9. The example method of FIG. 10 includes encoding a number of bits for transmission via channels of a multi-channel communications system into coded bits including systematic bits and parity bits at 400. The channels of the multi-channel communications system may include a more reliable channel and a less reliable channel. At 410, the example method includes allocating at least some systematic bits to bit locations within a first stream corresponding to the more reliable channel. According to various example embodiments, all of the bit locations within the first stream may be allocated to systematic bits. At 420, the example method may include allocating at least some remaining systematic bits to bit locations having a higher signal priority within a second stream corresponding to the less reliable channel. According to various example embodiments, some or all of the higher signal priority bit locations within the second stream may be allocated to systematic bits. At 430, the example method also includes allocating at least some or all of the parity bits to remaining available bit locations within the second stream. In some example embodiments, allocating at least some of the or all of the parity bits may include allocating some of the parity bits associated with the systematic bits allocated to the first stream to bit locations in the second stream.

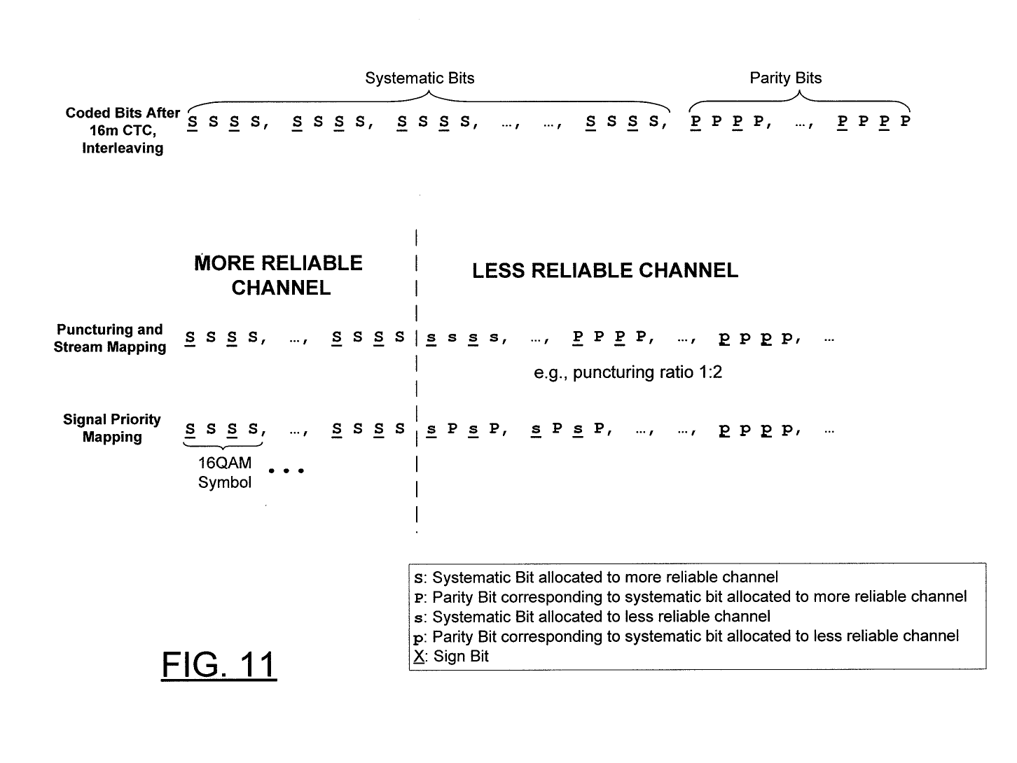

FIG. 11 depicts another bit allocation in accordance with an example embodiment. The bit allocation of FIG. 11 is determined using combined puncturing and CW-to-stream mapping based on signal/channel reliability with symbol mapping based on signal priority. In the example scenario depicted in FIG. 11, the number of information bits is 48, 16QAM modulation is used with a code rate ⅔, and two data streams are generated for transmission on respective channels. One channel has been determined to be more reliable than the other channel.

FIG. 11 depicts a sequence of coded systematic and parity bits generated after encoding and interleaving. The resultant coded bits may then be mapped through a CW-to-stream mapper based on signal reliability. In this regard, the systematic bits may be mapped to a stream corresponding to the more reliable channel. Any remaining systematic bits may be allocated to the less reliable channel, and all of the parity bits may be allocated to the stream corresponding to the less reliable channel.

The sequence of coded bits may then be punctured based on a puncturing ratio. In this regard, a determination may be made to identify a number of systematic bits remaining for allocation to the less reliable channel after the bit locations of the more reliable channel are filled with systematic bits. The puncturing ratio may be determined such that more parity bits associated with systematic bits to be allocated to the less reliable channel remain after puncturing than parity bits associated with systematic bits to be allocated to the more reliable channel. As depicted in FIG. 11, a 1:2 ratio is selected. In some example embodiments, CW-to-stream mapping based on reliability may be performed after puncturing.

Symbol mapping in accordance with SMP may be performed. In this regard, systematic bits allocated to the stream corresponding to the less reliable channel may be allocated to high signal priority bit locations (e.g., sign bit locations) of the complex-valued symbols and the parity bits may be allocated to the lower signal priority locations (e.g., non-sign bit locations). Accordingly, performance of the operations may result in a first stream of all systematic bits for the more reliable channel, and a stream having systematic bits in high signal priority bit locations for the less reliable channel. The parity bits may be allocated to lower signal priority locations within symbols having allocated systematic bits in the second stream, and any remaining parity bits may be allocated to any remaining available bit locations within the second stream.

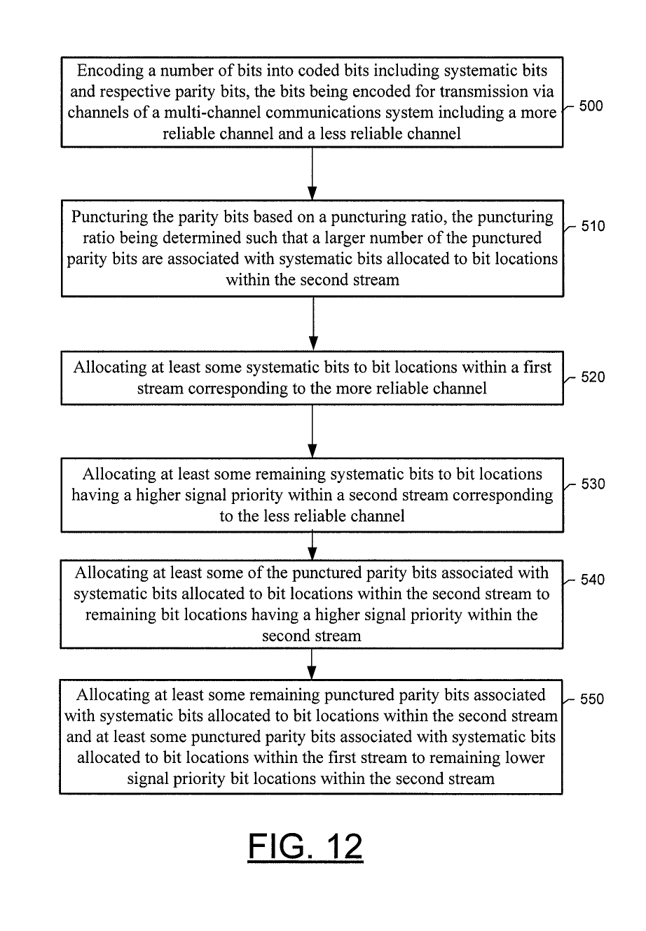

FIG. 12 depicts a flow chart of an example method for achieving the bit allocation depicted in FIG. 11. The example method of FIG. 12 includes encoding a number of bits for transmission via channels of a multi-channel communications system into coded bits including systematic bits and parity bits at 500. The channels of the multi-channel communications system may include a more reliable channel and a less reliable channel. At 510, the coded bits may be punctured based on a puncturing ratio. The puncturing ratio may be determined such that a larger number of the punctured parity bits are associated with systematic bits allocated to bit locations within the second stream. According to some example embodiments, puncturing may be performed in advance of allocation. At 520, the example method includes allocating at least some systematic bits to bit locations within a first stream corresponding to the more reliable channel. According to various example embodiments, all of the bit locations within the first stream may be allocated to systematic bits. At 530, the example method may include allocating at least some remaining systematic bits to bit locations having a higher signal priority within a second stream corresponding to the less reliable channel. At 540, the example method also includes allocating at least some punctured parity bits associated with systematic bits allocated to bit locations within the second stream to the remaining higher signal priority bit locations within the second stream. At 550, the example method may also include allocating at least some remaining punctured parity bits associated with systematic bits allocated to bit locations within the second stream, and at least some punctured parity bits associated with systematic bits allocated to bit locations within the first stream, to remaining lesser signal priority bit locations within the second stream.

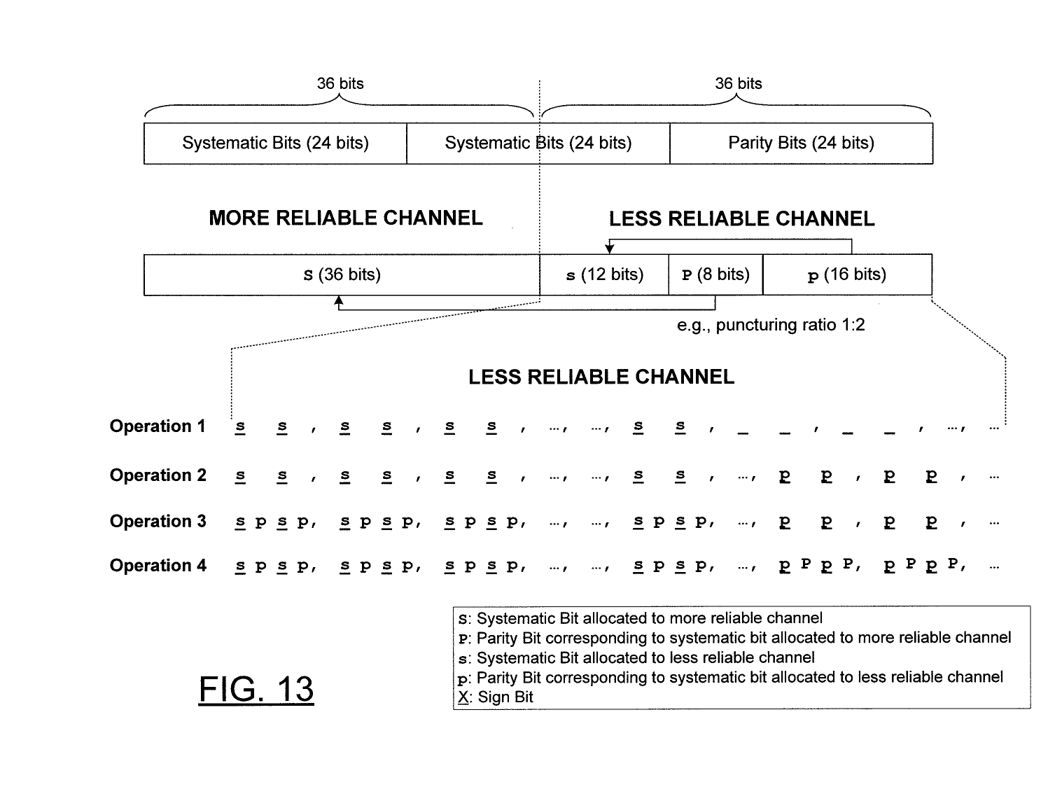

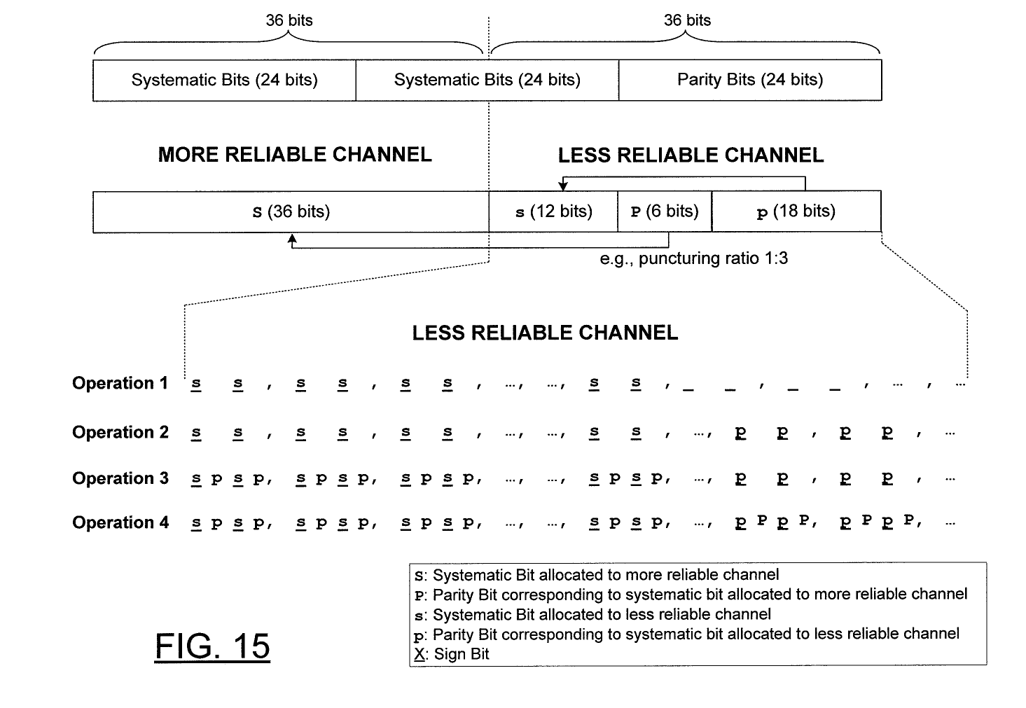

FIGS. 13 and 15 depict additional bit allocations determined using combined puncturing and CW-to-stream mapping based on signal/channel reliability with symbol mapping based on both signal priority and reliability. In the example scenario depicted in FIGS. 13 and 15, the number of information bits is 48, 16QAM modulation is used with a code rate ⅔, and two data streams are generated for transmission on respective channels. One channel has been determined to be more reliable than the other channel. The allocations of parity bits are considered with respect to both signal priority and signal/channel reliability.

FIG. 13 depicts a sequence of coded systematic and parity bits. The sequence includes 48 systematic bits and 24 parity bits. A predefined puncturing ratio of 1:2, as described above may be utilized. The bit allocation of FIG. 13 may be described with respect to a set of operations performed via CW-to-stream mapping and symbol mapping.

At the first operation of FIG. 13, the systematic bits may be allocated to the bit locations beginning in the more reliable channel, and any remaining systematic bits may be allocated to the higher signal priority bit locations in the less reliable channel. At the second operation, the puncture ratio may be used to determine a number of parity bits associated with systematic bits allocated to the less reliable channel. These associated parity bits may be allocated to remaining higher signal priority bit locations within the less reliable channel. At the third operation, any remaining parity bits associated with systematic bits that have been allocated to the less reliable channel may be allocated to the lesser signal priority bit locations within the symbols associated with the less reliable channel where systematic bits have been allocated to the higher signal priority bit locations. At the fourth operation, the parity bits associated with the systematic bits allocated to the more reliable channel may be allocated to the remaining lower signal priority locations within the less reliable channel.

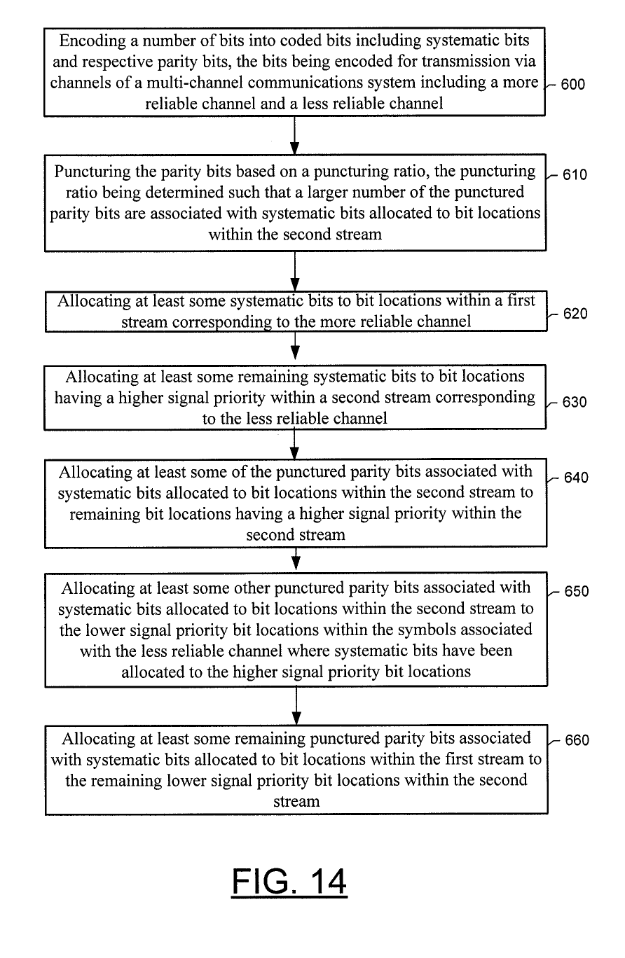

FIG. 14 depicts a flow chart of an example method for achieving the bit allocation depicted in FIG. 13. The example method of FIG. 13 includes encoding a number of bits for transmission via channels of a multi-channel communications system into coded bits including systematic bits and parity bits at 600. The channels of the multi-channel communications system may include a more reliable channel and a less reliable channel. At 610, the coded bits may be punctured based on a puncturing ratio. The puncturing ratio may be determined such that a larger number of the punctured parity bits are associated with systematic bits allocated to bit locations within the second stream. According to some example embodiments, puncturing may be performed in advance of allocation. At 620, the example method includes allocating at least some systematic bits to bit locations within a first stream corresponding to the more reliable channel. At 630, the example method may include allocating at least some remaining systematic bits to bit locations having a higher signal priority within a second stream corresponding to the less reliable channel. At 640, the example method also includes allocating at least some of the punctured parity bits associated with systematic bits allocated to bit locations within the second stream to remaining bit locations having a higher signal priority within the second stream. At 650, the example method includes allocating at least some remaining punctured parity bits associated with systematic bits allocated to bit locations within the second stream to the lower signal priority bit locations within the symbols associated with the less reliable channel where systematic bits have been allocated to the higher signal priority bit locations. In this regard, parity bits may be allocated to lower signal priority locations such that at least some parity bits are allocated to the same symbol as their associated systematic bits. The example method also includes, at 660, allocating at least some punctured parity bits associated with systematic bits allocated to bit locations within the first stream to remaining bit locations having a lower signal priority within the second stream.

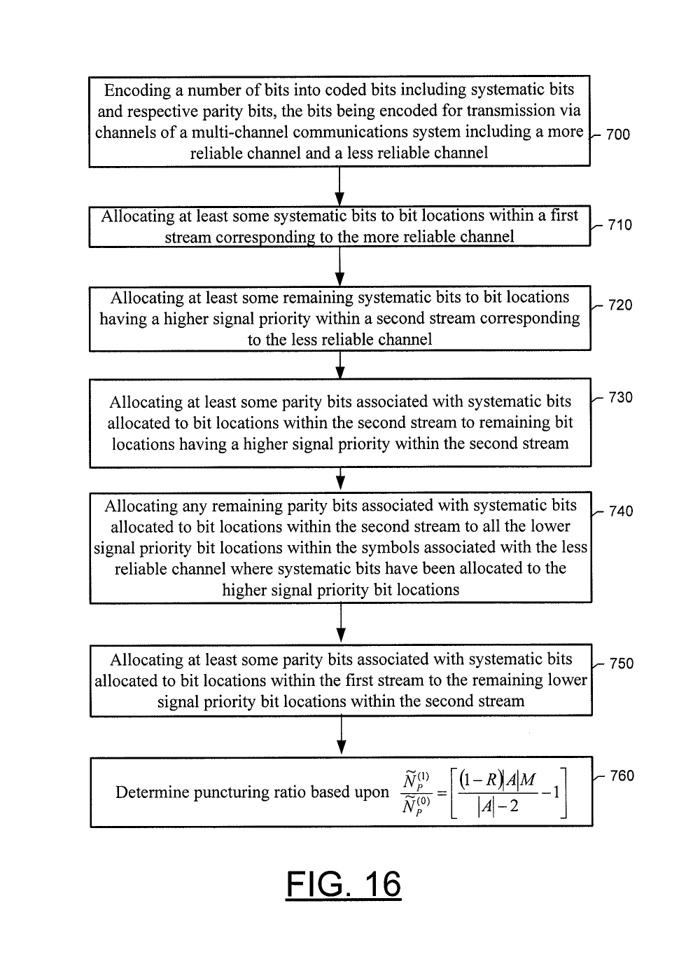

FIG. 15 depicts another sequence of coded systematic and parity bits. The sequence includes 48 systematic bits and 24 parity bits. Unlike the example embodiments described with respect to FIGS. 13 and 14, a puncturing ratio for example embodiments according to FIGS. 15 and 16 are not predefined, but rather determined using an equation as further described below. In the example scenario depicted in FIG. 15, the puncture ratio is determined to be 1:3. The bit allocation of FIG. 15 may be described with respect to a set of operations performed via CW-to-stream mapping and symbol mapping.

At the first operation of FIG. 15, the systematic bits may be allocated to the bit locations beginning in the more reliable channel, and any remaining systematic bits may be allocated to the higher signal priority bit locations in the less reliable channel. At the second operation, parity bits associated with the systematic bits allocated to the less reliable channel may be allocated to remaining higher signal priority bit locations within the less reliable channel. At the third operation, any remaining parity bits associated with systematic bits that have been allocated to the less reliable channel may be allocated to the lower signal priority bit locations within the symbols associated with the less reliable channel where systematic bits have been allocated to higher signal priority bit locations. At the fourth operation, the parity bits associated with the systematic bits allocated to the more reliable channel may be allocated to the remaining lower signal priority locations within the less reliable channel.

As mentioned above, the puncture ratio may be determined via calculation of a equation with respect to the modulation order |A|, the coding rate R, and the number of data streams M. As a foundation the follow relationship may be defined as

$${N}_{C} := \frac{{N}_{S}}{R} = {N}_{S} + {N}_{P} \qquad ( 1 )$$

where NC denotes the total number of coded bits after encoding, interleaving, and puncturing, with Ns being the number of systematic bits (i.e., equal to information bit number), and N_{P} being the number of parity bits.

A relationship with respect allocation of bits to the stream associated with the less reliable channel may also be defined. In this regard,

$${\tilde{N}}_{C} := \frac{{N}_{C}}{M} = {\tilde{N}}_{S} + {\tilde{N}}_{P} \qquad ( 2 )$$

where Ñ_{C} is the number of coded bits allocated to the less reliable channel, Ñ_{S} is the number of systematic bits allocated to the less reliable channel, and Ñ_{P} is the number of parity bits allocated to the less reliable channel. The number of high signal priority bits (e.g., sign bits) within the complex-value symbols that are placed in less reliable channel may be defined as

$$\begin{matrix}{\tilde{N}}_{Sign} := \frac{{\tilde{N}}_{C}}{\vert A \vert / 2} . & ( 3 ) \\ Additionally , & \\ {\tilde{N}}_{S} = {\tilde{N}}_{C} - ( {N}_{C} - {N}_{S} ) & ( 4 ) \\ and & \\ {\tilde{N}}_{P} := {\tilde{N}}_{P}^{( 0 )} + {\tilde{N}}_{P}^{( 1 )} = {\tilde{N}}_{C} - {\tilde{N}}_{S} & ( 5 )\end{matrix}$$

where Ñ_{P}⁽⁰⁾ is a number of parity bits associated with systematic bits allocated to the less reliable channel, and Ñ_{P}⁽¹⁾ is a number of parity bits associated with systematic bits allocated to the more reliable channel. Ñ_{P}⁽⁰⁾ and Ñ_{P}⁽¹⁾ may be calculated as follows:

$$\begin{matrix}{\tilde{N}}_{P}^{( 0 )} = ( \frac{\vert A \vert}{2} - 1 ) \\ {\tilde{N}}_{Sign} = \frac{\vert A \vert - 2}{R \vert A \vert M} {N}_{S} & ( 6 ) \\ and & \\ {\tilde{N}}_{P}^{( 1 )} = {N}_{P} - {\tilde{N}}_{P}^{( 0 )} = \frac{( 1 - R ) \vert A \vert M - \vert A \vert + 2}{R \vert A \vert M} {N}_{S} . & ( 7 )\end{matrix}$$

From equation (6) and equation (7), the puncture ratio may be determined as:

$$\begin{matrix}{R}_{ij} := {\tilde{N}}_{P}^{( 1 )} / {\tilde{N}}_{P}^{( 0 )} = {( \frac{( 1 - R ) \vert A \vert M}{\vert A \vert - 2} - 1 )}^{+} & ( 8 ) \\ where & \\ {( x )}^{+} = \{ \begin{matrix}x & x > 0 \\ 0 & x <= 0.\end{matrix} & ( 9 )\end{matrix}$$

FIG. 16 depicts a flow chart of an example method for achieving the bit allocation depicted in FIG. 15. The example method of FIG. 16 includes encoding a number of bits for transmission via channels of a multi-channel communications system into coded bits including systematic bits and parity bits at 700. The channels of the multi-channel communications system may include a more reliable channel and a less reliable channel. At 710, the example method includes allocating at least some systematic bits to bit locations within a first stream corresponding to the more reliable channel. At 720, the example method may include allocating at least some remaining systematic bits to bit locations having a higher signal priority within a second stream corresponding to the less reliable channel. At 730, the example method also includes allocating at least some parity bits associated with systematic bits allocated to bit locations within the second stream to remaining bit locations having a higher signal priority within the second stream. At 740, the example method includes allocating any remaining parity bits associated with systematic bits allocated to bit locations within the second stream to all the lower signal priority bit locations within the symbols associated with the less reliable channel where systematic bits have been allocated to the higher signal priority bit locations. The example method also includes, at 750, allocating at least some parity bits associated with systematic bits allocated to bit locations within the first stream to remaining bit locations having a lower signal priority within the second stream. At 760, the example method includes determining a puncture ratio based on equations (8) and (9), as described above.

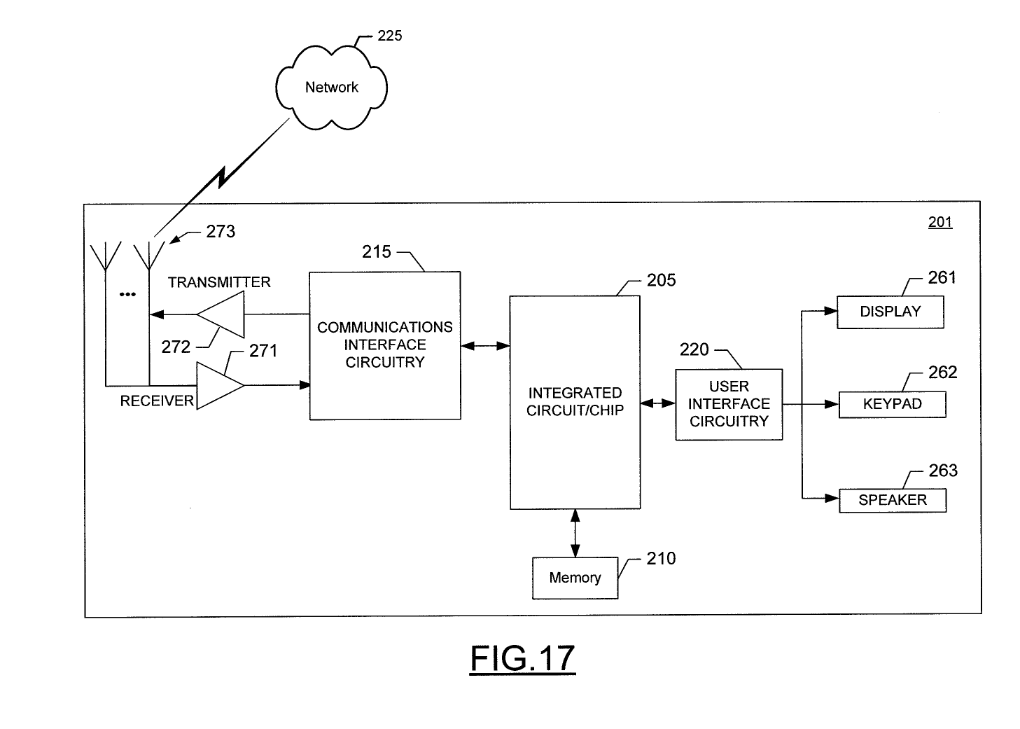

The description provided above and generally herein illustrates example methods, example apparatuses, and example computer program products for data transmission based on signal priority and channel reliability. FIG. 17 illustrates example apparatus embodiments in the form of an integrated circuit/chip 200 or a communications apparatus 201 configured to perform the various functionalities described herein. The integrated circuit/chip 200 or the apparatus 201 may include and/or be configured to implement the functionality described herein, and in particular, the functionality described with respect to FIGS. 8-16. For example, integrated circuit/chip 200 may include, or be configured to perform the functionality of, the encoder 126, then channel interleaver 128, the rate matcher 156, the CW-to-stream mapper 158, the symbol mapper 160, the precoder 136, and the controller 162.

Referring now to FIG. 17, in some example embodiments, the apparatus 201 may, be embodied as, or included as a component of, a communications device with wired or wireless communications capabilities. As a stationary terminal, the apparatus 201 may be part of an access point (e.g., a base station, wireless router, or the like), a computer, a server, a device that supports network communications, or the like. As a mobile terminal, the apparatus 201 may be a mobile computer, mobile telephone, a portable digital assistant (PDA), a pager, a mobile television, a gaming device, a mobile computer, a laptop computer, a camera, a video recorder, an audio/video player, a radio, and/or a global positioning system (GPS) device, any combination of the aforementioned, or the like. Regardless of the type of communications device, apparatus 201 may also include computing capabilities.

The example apparatus 201 includes or is otherwise in communication with a integrated circuit/chip 205, a memory device 210, a communications interface circuitry 215, receiver 271, transmitter 272, antennas 273, user interface circuitry 220, display 261, keypad 262, and speaker 263. The integrated circuit/chip 205 may be embodied as various means for implementing the various functionalities of example embodiments including, for example, a microprocessor, a coprocessor, a controller, a special-purpose integrated circuit such as, for example, an ASIC (application specific integrated circuit), an FPGA (field programmable gate array), or a hardware accelerator, processing circuitry or the like. In some example embodiments, the integrated circuit/chip 205 is configured to execute instructions stored in the memory device 210 or instructions otherwise accessible to the integrated circuit/chip 205. In this regard, the instructions stored in memory device 210 may be instructions to perform the functionally described with respect to FIGS. 8-16.

Whether configured as hardware or via instructions stored on a computer-readable storage medium, or by a combination thereof, the integrated circuit/chip 205 may be an entity capable of performing operations according to embodiments while configured accordingly. Thus, in example embodiments where the integrated circuit/chip 205 is embodied as, or is part of, an ASIC, FPGA, or the like, the integrated circuit/chip 205 is specifically configured hardware for conducting the operations described herein. Alternatively, in example embodiments where the integrated circuit/chip 205 is embodied as an executor of instructions stored on a computer-readable storage medium, the instructions specifically configure the integrated circuit/chip 205 to perform the algorithms and operations described herein. In some example embodiments, the integrated circuit/chip 205 is a processor of a specific device (e.g., a mobile terminal) configured for employing example embodiments by further configuration of the integrated circuit/chip 205 via executed instructions for performing the algorithms, methods, and operations described herein.

The memory device 210 may be one or more computer-readable storage media that may include volatile and/or non-volatile memory. In some example embodiments, the memory device 210 includes Random Access Memory (RAM) including dynamic and/or static RAM, on-chip or off-chip cache memory, and/or the like. Further, memory device 210 may include non-volatile memory, which may be embedded and/or removable, and may include, for example, read-only memory, flash memory, magnetic storage devices (e.g., hard disks, floppy disk drives, magnetic tape, etc.), optical disc drives and/or media, non-volatile random access memory (NVRAM), and/or the like. Memory device 210 may include a cache area for temporary storage of data. In this regard, some or all of memory device 210 may be included within the integrated circuit/chip 205.

The communication interface circuitry 215 may be any device or means embodied in either hardware, a computer program product, or a combination of hardware and a computer program product that is configured to receive and/or transmit data from/to a network 225 and/or any other device or module in communication with the example apparatus 201 via the receiver 271, the transmitter 272, and the antennas 273. Integrated circuit/chip 205 may also be configured to facilitate communications via the communications interface circuitry by, for example, controlling hardware included within the communications interface 215. Further, the integrated circuit/chip 205 and communications interface circuitry 215, together with the receiver 271, the transmitter 272, and the antennas 273, may be configured to support any type of wireless communications including communications with MIMO environments and environments implementing orthogonal frequency division multiplexed (OFDM) signaling.

The user interface circuitry 220 may be in communication with the integrated circuit/chip 205 to receive user input or provide user output via the display 261, keypad 262, and the speaker 263. According to some example embodiments, such as embodiments where the apparatus 201 is a base station, the user interface circuitry 260, the display 261, the keypad 262, and the speaker 263 may be eliminated.

FIGS. 10, 12, 14, and 16 illustrates flowcharts of example systems, methods, and/or computer program products according to example embodiments. It will be understood that each block or operation of the flowcharts, and/or combinations of blocks or operations in the flowcharts, can be implemented by various means. Means for implementing the blocks or operations of the flowcharts, combinations of the blocks or operations in the flowchart, or other functionality of example embodiments described herein may include hardware, and/or a computer program product including a computer-readable storage medium having one or more computer program code instructions, program instructions, or executable computer-readable program code instructions stored therein. In this regard, program code instructions may be stored on a memory device, such as memory device 210, of an example apparatus, such as example apparatus 201, and executed by the elements described with respect to FIG. 8, or a processor, such as the integrated circuit/chip 205. As will be appreciated, any such program code instructions may be loaded onto a computer or other programmable apparatus (e.g., integrated circuit/chip 205, memory device 210, or the like) from a computer-readable storage medium to produce a particular machine, such that the particular machine becomes a means for implementing the functions specified in the flowcharts' block(s) or operation(s). These program code instructions may also be stored in a computer-readable storage medium that can direct a computer, a processor, or other programmable apparatus to function in a particular manner to thereby generate a particular machine or particular article of manufacture. The instructions stored in the computer-readable storage medium may produce an article of manufacture, where the article of manufacture becomes a means for implementing the functions specified in the flowcharts' block(s) or operation(s). The program code instructions may be retrieved from a computer-readable storage medium and loaded into a computer, processor, or other programmable apparatus to configure the computer, processor, or other programmable apparatus to execute operations to be performed on or by the computer, processor, or other programmable apparatus. Retrieval, loading, and execution of the program code instructions may be performed sequentially such that one instruction is retrieved, loaded, and executed at a time. In some example embodiments, retrieval, loading and/or execution may be performed in parallel such that multiple instructions are retrieved, loaded, and/or executed together. Execution of the program code instructions may produce a computer-implemented process such that the instructions executed by the computer, processor, or other programmable apparatus provide operations for implementing the functions specified in the flowcharts' block(s) or operation(s).

Accordingly, execution of instructions associated with the blocks or operations of the flowchart by a processor, or storage of instructions associated with the blocks or operations of the flowcharts in a computer-readable storage medium, support combinations of operations for performing the specified functions. It will also be understood that one or more blocks or operations of the flowcharts, and combinations of blocks or operations in the flowcharts, may be implemented by special purpose hardware-based computer systems and/or processors which perform the specified functions, or combinations of special purpose hardware and program code instructions.

Many modifications and other embodiments set forth herein will come to mind to one skilled in the art to which these embodiments pertain having the benefit of the teachings presented in the foregoing descriptions and the associated drawings. Therefore, it is to be understood that the embodiments are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions other than those explicitly described above are also contemplated as may be set forth in some of the appended claims. Although specific terms are employed herein, they are used in a generic and descriptive sense only and not for purposes of limitation.

What is claimed is:

1. A method comprising:
encoding a number of bits into coded bits including systematic bits and respective associated parity bits, the bits being encoded for transmission via channels of a multi-channel communications system including a more reliable channel and a less reliable channel; and
allocating the systematic bits and the parity bits to respective bit locations within a first stream corresponding to the more reliable channel, or respective bit locations within a second stream corresponding to the less-reliable channel, allocating the systematic bits and the parity bits including:
allocating at least some systematic bits to bit locations within the first stream;
allocating at least some remaining systematic bits to bit locations having a higher signal priority within the second stream; and
allocating at least some parity bits to remaining available bit locations within the second stream.

2. The method of claim 1, wherein the bit locations having the higher signal priority are sign bit locations corresponding to modulated symbols.

3. The method of claim 1, wherein allocating the systematic bits and the parity bits further comprises allocating at least some other parity bits to bit locations having a lower signal priority within the second stream, the at least some other parity bits being allocated to bit locations associated with symbols having systematic bits allocated to the bit locations having the higher signal priority.

4. The method of claim 1 further comprising:
puncturing the parity bits based on a puncturing ratio, the puncturing ratio being determined such that a larger number of the punctured parity bits are associated with systematic bits allocated to bit locations within the second stream.

5. The method of claim 4, wherein allocating the systematic bits and the parity bits further comprises allocating at least some of the punctured parity bits associated with systematic bits allocated to bit locations within the second stream to remaining bit locations having a higher signal priority within the second stream.

6. The method of claim 5, wherein allocating the systematic bits and the parity bits further comprises allocating at least some remaining punctured parity bits associated with systematic bits allocated to bit locations within the second stream and at least some remaining punctured parity bits associated with systematic allocated to bit locations within the first stream to remaining lower signal priority bit locations within the second stream.

7. The method of claim 5, wherein allocating at least some parity bits includes allocating at least some other punctured parity bits associated with systematic bits allocated to bit locations within the second stream to the lower signal priority bit locations within the symbols associated with the less reliable channel where systematic bits have been allocated to the higher signal priority bit locations; and allocating at least some remaining punctured parity bits associated with systematic bits allocated to bit locations within the first stream to the remaining lower signal priority bit locations within the second stream.

8. The method of claim 7, further comprising mapping groups of the allocated systematic bits and parity bits within the second stream to symbols; wherein each of one or more of the symbols is mapped from a group including systematic bits allocated to high signal priority bit locations and parity bits allocated to low signal priority bit locations.

9. The method of claim 1, further comprising mapping groups of the allocated systematic bits and parity bits to a symbol; wherein each of one or more of the symbols is mapped from a group including both systematic bits and parity bits.

10. The method of claim 1 further comprising determining a puncturing ratio Ñ_{P}⁽¹⁾/Ñ_{P}⁽⁰⁾, where Ñ_{P}⁽¹⁾ is a number of parity bits associated with systematic bits allocated to the first stream and Ñ_{P}⁽⁰⁾ is a number of parity bits associated with systematic bits allocated to the second stream, the ratio being determined based on the relationship:
$$\frac{{\tilde{N}}_{P}^{( 1 )}}{{\tilde{N}}_{P}^{( 0 )}} = [ \frac{( 1 - R ) \vert A \vert M}{\vert A \vert - 2} - 1 ] ,$$
where R is a coding rate, M is a number of streams, and |A| is a modulation order; and wherein the method further comprises puncturing the parity bits based on the puncturing ratio.

11. The method of claim 1, further comprising mapping groups of the allocated systematic bits and parity bits within the first stream to symbols; wherein each of one or more of the symbols is mapped from a group including systematic bits allocated to high signal priority bit locations and associated parity bits allocated to low signal priority bit locations.

12. An apparatus comprising:
an encoder configured to encode a number of bits into coded bits including systematic bits and respective associated parity bits, the bits being encoded for transmission via channels of a multi-channel communications system including a more reliable channel and a less reliable channel; and
a bit mapper configured to allocate the systematic bits and the parity bits to respective bit locations within a first stream corresponding to the more reliable channel, or respective bit locations within a second stream corresponding to the less-reliable channel, being configured to allocate the systematic bits and the parity bits includes being configured to:
allocate at least some systematic bits to bit locations within the first stream
allocate at least some remaining systematic bits to bit locations having a higher signal priority within the second stream, and
allocate at least some parity bits to remaining available bit locations within the second stream.

13. The apparatus of claim 12, wherein the bit locations having the higher signal priority are sign bit locations corresponding to modulated symbols.

14. The apparatus of claim 12, wherein the bit mapper configured to allocate the systematic bits and the parity bits is further configured to allocate at least some other parity bits to bit locations having a lower signal priority within the second stream, the at least some other parity bits being allocated to bit locations associated with symbols having systematic bits allocated to the bit locations having the higher signal priority.

15. The apparatus of claim 12 further comprising a rate matcher configured to puncture the parity bits based on a puncturing ratio, the puncturing ratio being determined such that a larger number of the punctured parity bits are associated with systematic bits allocated to bit locations within the second stream.

16. The apparatus of claim 15, wherein the bit mapper is further configured to allocate at least some of the punctured parity bits associated with systematic bits allocated to bit locations within the second stream to remaining bit locations having a higher signal priority within the second stream.

17. The apparatus of claim 16, wherein the bit mapper is further configured to allocate at least some remaining punctured parity bits associated with systematic bits allocated to bit locations within the second stream and at least some remaining punctured parity bits associated with systematic allocated to bit locations within the first stream to remaining lower signal priority bit locations within the second stream.

18. The apparatus of claim 16, wherein the bit mapper configured to allocate at least some parity bits includes being configured to allocate at least some other punctured parity bits associated with systematic bits allocated to bit locations within the second stream to the lower signal priority bit locations within the symbols associated with the less reliable channel where systematic bits have been allocated to the higher signal priority bit locations; and allocating at least some remaining punctured parity bits associated with systematic bits allocated to bit locations within the first stream to the remaining lower signal priority bit locations within the second stream.

19. The apparatus of claim 18, wherein the bit mapper is further configured to map groups of the allocated systematic bits and parity bits within the second stream to symbols; wherein each of one or more of the symbols is mapped from a group including systematic bits allocated to high signal priority bit locations and parity bits allocated to low signal priority bit locations.

20. The apparatus of claim 12, wherein the bit mapper is further configured to map groups of the allocated systematic bits and parity bits to a symbol; wherein each of one or more of the symbols is mapped from a group including both systematic bits and parity bits.

21. The apparatus of claim 12, further comprising a controller configured to determine a puncturing ratio Ñ_{P}⁽¹⁾/Ñ_{P}⁽⁰⁾, where Ñ_{P}⁽¹⁾ is a number of parity bits associated with systematic bits allocated to the first stream and Ñ_{P}⁽⁰⁾ is a number of parity bits associated with systematic bits allocated to the second stream, the ratio being determined based on the relationship:
$$\frac{{\tilde{N}}_{P}^{( 1 )}}{{\tilde{N}}_{P}^{( 0 )}} = [ \frac{( 1 - R ) \vert A \vert M}{\vert A \vert - 2} - 1 ] ,$$
where R is a coding rate, M is a number of streams, and |A| is a modulation order; and a rate matcher configured to puncture the parity bits based on the puncturing ratio.

22. The apparatus of claim 12, wherein the bit mapper is further configured to map groups of the allocated systematic bits and parity bits within the first stream to symbols; wherein each of one or more of the symbols is mapped from a group including systematic bits allocated to high signal priority bit locations and associated parity bits allocated to low signal priority bit locations.

23. A computer program product comprising at least one computer-readable storage medium having executable computer-readable program code instructions stored therein, the computer-readable program code instructions configured to cause an apparatus to perform:
encoding a number of bits into coded bits including systematic bits and respective associated parity bits, the bits being encoded for transmission via channels of a multi-channel communications system including a more reliable channel and a less reliable channel; and
allocating the systematic bits and the parity bits to respective bit locations within a first stream corresponding to the more reliable channel, or respective bit locations within a second stream corresponding to the less-reliable channel, allocating the systematic bits and the parity bits including:
allocating at least some systematic bits to bit locations within the first stream,
allocating at least some remaining systematic bits to bit locations having a higher signal priority within the second stream, and
allocating at least some parity bits to remaining available bit locations within the second stream.
